(19) United States
(12) Patent Application Publication
(10) Pub. No.: US 2017/0309704 A1
(43) Pub. Date: Oct. 26, 2017

(54) SEMICONDUCTOR DEVICE AND MANUFACTURING METHOD THEREFOR

(71) Applicant: Mitsubishi Electric Corporation, Tokyo (JP)

(72) Inventor: Kenji SUZUKI, Tokyo (JP)

(73) Assignee: Mitsubishi Electric Corporation, Tokyo (JP)

(21) Appl. No.: 15/511,650

(22) PCT Filed: Jan. 14, 2015
(86) PCT No.: PCT/JP2015/050799

§ 371 Date: Mar. 16, 2017

(51) Int. Cl. H01L 29/06; H01L 29/66; H01L 29/10; H01L 29/739; H01L 21/761

(52) U.S. Cl. CPC H01L 29/0623; H01L 29/7397; H01L 21/761; H01L 29/1095; H01L 29/66348

(57) ABSTRACT

Trenches (8,9,10) are formed on a front surface side of an n-type semiconductor substrate (3) and penetrate a p-type base layer (4) and an n-type layer (5). A distance between the trench (8) and the trench (9) is smaller than a distance between the trench (9) and the trench (10). The n-type emitter layer (6) is formed in a cell region between the trench (8) and the trench (9). The p-type well region (11) is formed in a dummy region between the trench (9) and the trench (10). An outermost surface part of the n-type semiconductor substrate (3) is of only a p-type in the dummy region. The p-type well region (11) is deeper than the trenches (8,9,10).

### FIELD

The present invention relates to a structure of an Insulated Gate Bipolar Transistor (IGBT) and a manufacturing method therefor.

### BACKGROUND

IGBTs are used for power modules or the like for variable speed control of three-phase motors in the fields of general-purpose inverters and AC servos or the like from the standpoint of energy saving. Although IGBTs have a trade-off relationship between switching loss and ON voltage or SOA (safe operating area), there is a demand for devices having low switching loss, low ON voltage and wide SOA.

Most of an ON voltage is applied to a resistor of a thick n⁻-type drift layer necessary to maintain a withstand voltage, and for reducing the resistance, it is effective to accumulate holes from the rear surface in the n⁻-type drift layer, activate conductivity modulation and reduce the resistance of the n⁻-type drift layer. Examples of a device with a reduced ON voltage of IGBT include CSTBT (carrier stored trench gate bipolar transistor) and IEGT (injection enhanced gate transistor). An example of the CSTBT is disclosed in PTL 1 or the like and an example of the IEGT is disclosed in PTL 2 or the like.

### CITATION LIST

### Parent Literature

PTL 1: Japanese Patent No. 3288218

PTL 2: Japanese Patent No. 2950688

### SUMMARY

### Technical Problem

The CSTBT which is one of trench-type IGBTs includes an n⁺-type layer provided below a p-type base layer. Inclusion of the n⁺-type layer makes it possible to cause a diffusion potential formed in an n⁻-type drift layer and an n⁺-type layer to accumulate holes from the rear surface in the n⁻-type drift layer and reduce the ON voltage. However, when the cell size increases, the carrier accumulation effect increases, the ON voltage decreases and the characteristic improves, whereas there is a problem that the withstand voltage conversely decreases.

The present invention has been implemented to solve the above-described problems and it is an object of the present invention to provide a semiconductor device and a manufacturing method therefor capable of improving a withstand voltage while securing a low ON voltage.

### Solution to Problem

A semiconductor device according to the present invention includes: an n-type semiconductor substrate; a p-type base layer formed on a front surface side of the n-type semiconductor substrate; an n-type layer formed below the p-type base layer on the front surface side of the n-type semiconductor substrate and having a higher impurity concentration than that of the n-type semiconductor substrate; an n-type emitter layer formed on the p-type base layer; first, second and third trenches formed on the front surface side of the n-type semiconductor substrate and penetrating the p-type base layer and the n-type layer; a trench gate electrode formed in the first trench via an insulating film; an emitter electrode formed on the p-type base layer and the n-type emitter layer and electrically connected to the p-type base layer and the n-type emitter layer respectively; a p-type collector layer formed on a rear surface side of the n-type semiconductor substrate; a collector electrode connected to the p-type collector layer; and a p-type well region formed on the front surface side of the n-type semiconductor substrate, wherein a distance between the first trench and the second trench is smaller than a distance between the second trench and the third trench, the n-type emitter layer is formed in a cell region between the first trench and the second trench, the p-type well region is formed in a dummy region between the second trench and the third trench, an outermost surface part of the n-type semiconductor substrate is of only a p-type in the dummy region, and the p-type well region is deeper than the first, second and third trenches.

### Advantageous Effects of Invention

In the present invention, the p-type well region which is deeper than the trenches is formed in a region which is wider than the MOS region. Therefore, the withstand voltage can be improved while securing a low ON voltage.

### BRIEF DESCRIPTION OF THE DRAWINGS

FIG. 1 is a plan view illustrating a semiconductor device according to a first embodiment of the present invention.

FIG. 2 is a cross-sectional view illustrating the semiconductor device according to the first embodiment of the present invention.

FIG. 3 is a partially enlarged plan view of the semiconductor device according to the first embodiment of the present invention.

FIG. 4 is a cross-sectional view illustrating the method for manufacturing the semiconductor device according to the first embodiment of the present invention.

FIG. 5 is a cross-sectional view illustrating the method for manufacturing the semiconductor device according to the first embodiment of the present invention.

FIG. 6 is a cross-sectional view illustrating the method for manufacturing the semiconductor device according to the first embodiment of the present invention.

FIG. 7 is a cross-sectional view illustrating the method for manufacturing the semiconductor device according to the first embodiment of the present invention.

FIG. 8 is a cross-sectional view illustrating the method for manufacturing the semiconductor device according to the first embodiment of the present invention.

FIG. 9 is a cross-sectional view illustrating the method for manufacturing the semiconductor device according to the first embodiment of the present invention.

FIG. 10 is a cross-sectional view illustrating the method for manufacturing the semiconductor device according to the first embodiment of the present invention.

FIG. 11 is a cross-sectional view illustrating a semiconductor device according to the comparative example.

FIG. 12 is a diagram illustrating a relationship between a cell size and an ON voltage of the IGBT investigated in a device simulation.

FIG. 13 is a diagram illustrating a relationship between a cell size and a withstand voltage of the IGBT investigated in a device simulation.

FIG. 14 is a diagram illustrating an electric field distribution of the IGBT according to the comparative example investigated in a device simulation when the withstand voltage is maintained.

FIG. 15 is a diagram illustrating an electric field distribution of the IGBT according to the first embodiment investigated in a device simulation when the withstand voltage is maintained.

FIG. 16 is a cross-sectional view illustrating a method for manufacturing a semiconductor device according to a second embodiment of the present invention.

FIG. 17 is a cross-sectional view illustrating a semiconductor device according to a third embodiment of the present invention.

FIG. 18 is a cross-sectional view illustrating a semiconductor device according to a fourth embodiment of the present invention.

### DESCRIPTION OF EMBODIMENTS

A semiconductor device and a manufacturing method therefor according to the embodiments of the present invention will be described with reference to the drawings. The same components will be denoted by the same symbols, and the repeated description thereof may be omitted.

### First Embodiment

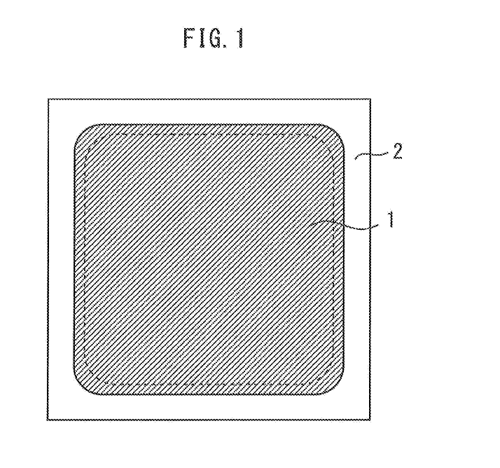

FIG. 1 is a plan view illustrating a semiconductor device according to a first embodiment of the present invention. A termination region 2 for keeping a withstand voltage is formed in an outer circumferential part of a transistor region 1 of an IGBT. When a voltage is applied between an emitter and a collector of the IGBT, a depletion layer extends in a lateral direction in the termination region 2, thus relaxing an electric field at an end of the transistor region 1.

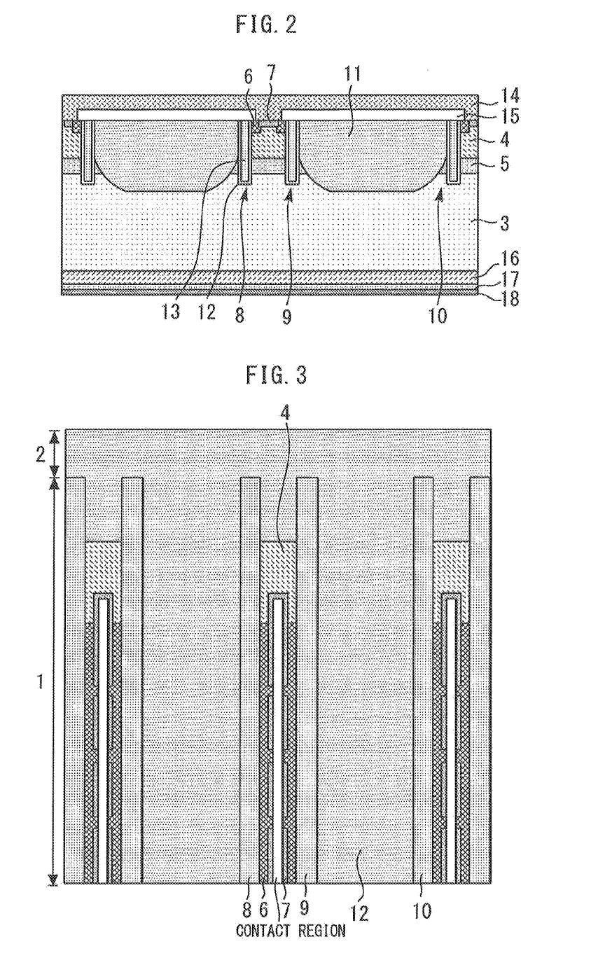

FIG. 2 is a cross-sectional view illustrating the semiconductor device according to the first embodiment of the present invention. In the entire transistor region 1 excluding an ineffective region such as the termination region 2, a p-type base layer 4 is formed on a front surface side of an n-type semiconductor substrate 3, and an n⁺-type layer 5 is formed below the p-type base layer 4. The n⁺-type layer 5 has a higher impurity concentration than that of the n-type semiconductor substrate 3. An n⁺-type emitter layer 6 and a p⁺-type contact layer 7 are formed on the p-type base layer 4. Trenches 8, 9 and 10 are formed on the front surface side of the n-type semiconductor substrate 3 in the transistor region 1, penetrating the p-type base layer 4 and the n⁺-type layer 5. A p-type well region 11 is formed on the front surface side of the n-type semiconductor substrate 3.

A trench gate electrode 13 is formed in the trenches 8, 9 and 10 via an insulating film 12. An emitter electrode 14 is formed on the p-type base layer 4 and the n⁺-type emitter layer 6, and electrically connected to those layers respectively. An inter-layer insulating film 15 insulates and separates the p-type well region 11 from the emitter electrode 14. An n⁺-type buffer layer 16 and a p⁺-type collector layer 17 are formed on the rear surface side of the n-type semiconductor substrate 3. A collector electrode 18 is connected to the p⁺-type collector layer 17.

The distance between the trench 8 and the trench 9 is smaller than the distance between the trench 9 and the trench 10. The n⁺-type emitter layer 6 and the p⁺-type contact layer 7 are formed in a narrower cell region between the trench 8 and the trench 9, and thus a MOS transistor channel is formed. The p-type well region 11 is formed in a wider dummy region between the trench 9 and the trench 10. In the dummy region, the outermost surface part of the n-type semiconductor substrate 3 is of only a p-type. The p-type well region 11 is deeper than the trenches 8, 9 and 10. However, the p-type well region 11 is disposed so as not to affect the characteristic of the MOS transistor formed in the narrower region between the trenches.

FIG. 3 is a partially enlarged plan view of the semiconductor device according to the first embodiment of the present invention. The p-type well region 11 exists in plurality in mutually separate regions in a plan view perpendicular to the front surface of the n-type semiconductor substrate 3, and the p-type well regions 11 are connected to each other so as to surround end portions of the trenches 8, 9 and 10.

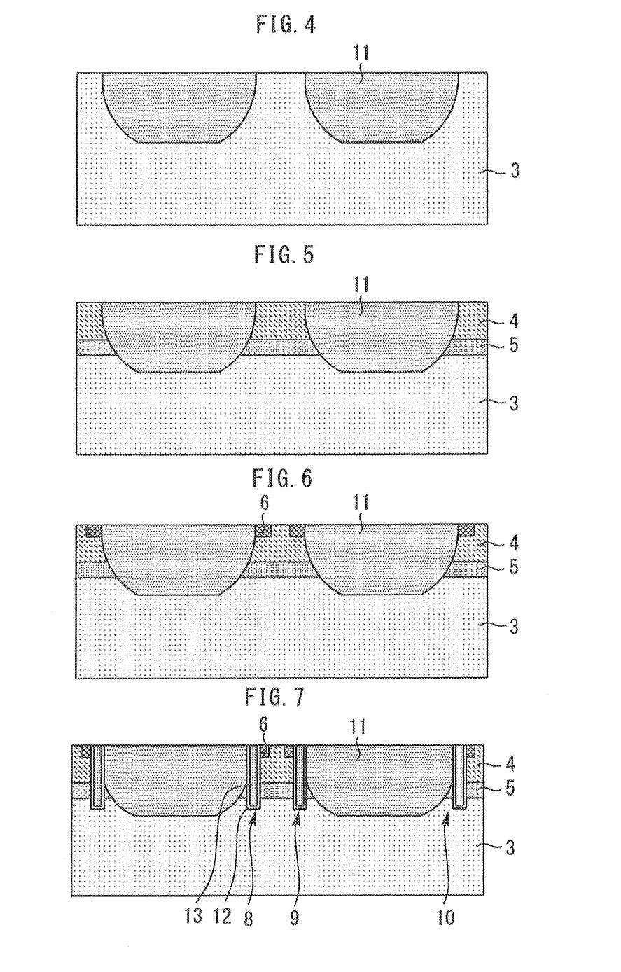

Next, a method for manufacturing the semiconductor device according to the present embodiment will be described. FIGS. 4 to 10 are cross-sectional views illustrating the method for manufacturing the semiconductor device according to the first embodiment of the present invention.

First, as shown in FIG. 4, a p-type impurity such as B is injected into the front surface of the n-type semiconductor substrate 3 using a photoengraving process technique and an injection technique to selectively form the p-type well regions 11 in the transistor region 1 and the termination region 2. Since the p-type well region 11 is required to have a large diffusion depth of 5 μm or above, the impurity is injected with high energy of 1 MeV or above using a MeV injector so that a concentration peak is formed inside the substrate.

Next, as shown in FIG. 5, using the photoengraving process technique and the injection technique, a p-type impurity such as B is injected into the entire transistor region 1 to form the p-type base layer 4, and an n-type impurity such as P is injected to form the n⁺-type layer 5. In order to reduce the manufacturing cost by reducing the number of steps, it is preferable to form the p-type base layer 4 and the n⁺-type layer 5 by impurity injection using a single mask. Next, as shown in FIG. 6, an n-type impurity such as As is selectively injected to form the n⁺-type emitter layer 6.

Next, as shown in FIG. 7, the trenches 8, 9 and 10 that penetrate the p-type base layer 4 and the n⁺-type layer 5 are formed by dry etching in the front surface side of the n-type semiconductor substrate 3. Doped polysilicon is embedded in the trenches 8, 9 and 10 via the insulating film 12 by CVD or the like to form the trench gate electrode 13.

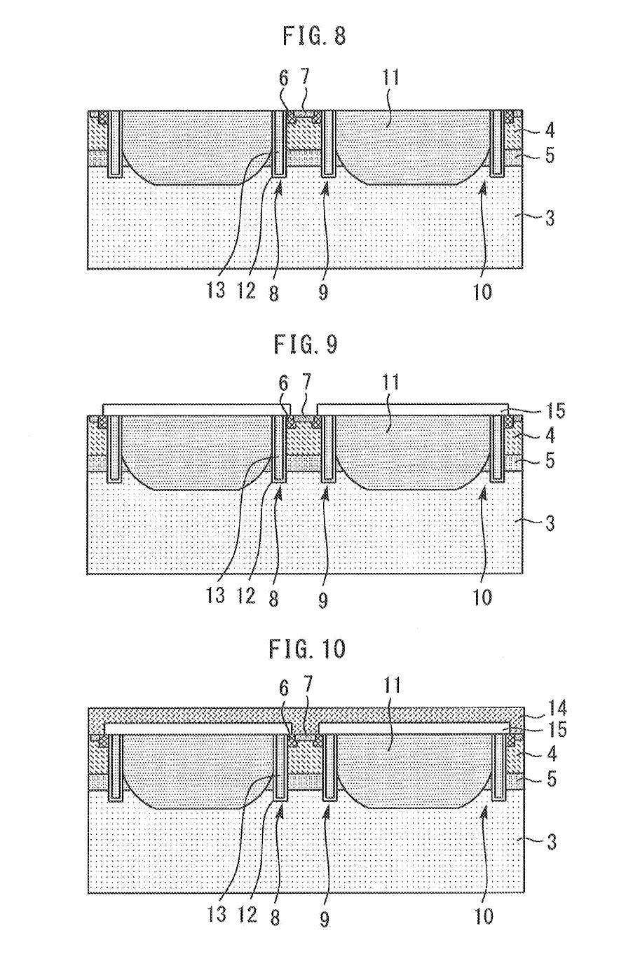

Next, as shown in FIG. 8, a p-type impurity such as B is injected and the p⁺-type contact layer 7 is selectively formed. Next, as shown in FIG. 9, after forming the inter-layer insulating film 15, a contact pattern is formed. Next, as shown in FIG. 10, the emitter electrode 14 is selectively formed using Al or AlSi or the like. After that, the n-type semiconductor substrate 3 is ground from the rear surface so as to reach a desired thickness, and the n⁺-type buffer layer 16 and the p⁺-type collector layer 17 are formed by injection or activation annealing to finally form the collector electrode 18.

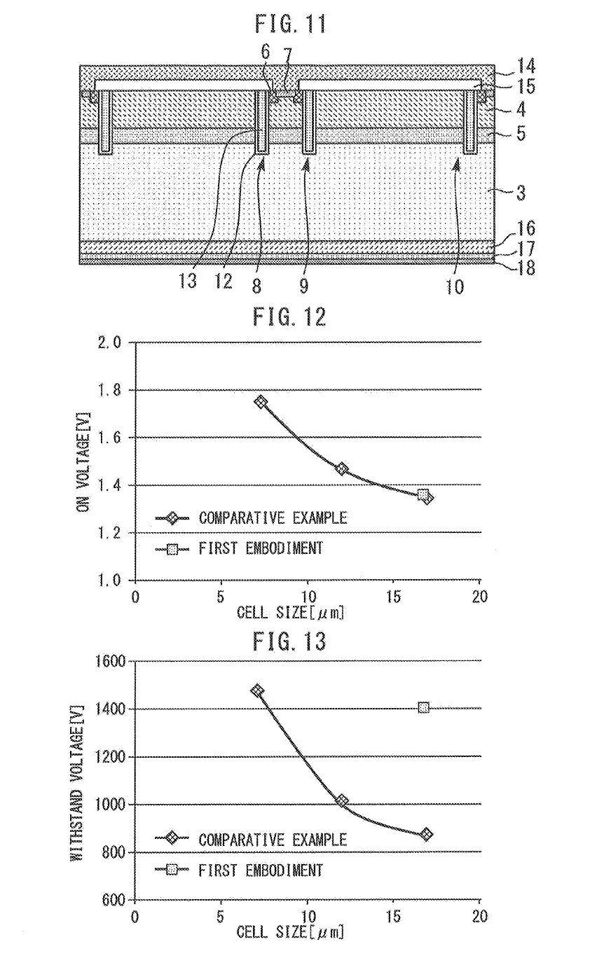

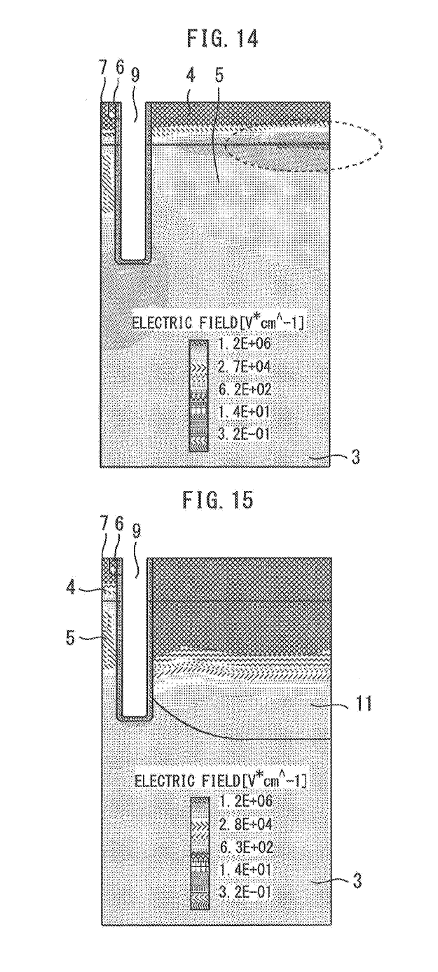

Next, effects of the present embodiment will be described in comparison with a comparative example. FIG. 11 is a cross-sectional view illustrating a semiconductor device according to the comparative example. No p-type well region 11 exists in the comparative example. FIG. 12 is a diagram illustrating a relationship between a cell size and an ON voltage of the IGBT investigated in a device simulation. FIG. 13 is a diagram illustrating a relationship between a cell size and a withstand voltage of the IGBT investigated in a device simulation. FIG. 14 is a diagram illustrating an electric field distribution of the IGBT according to the comparative example investigated in a device simulation when the withstand voltage is maintained. FIG. 15 is a diagram illustrating an electric field distribution of the IGBT according to the first embodiment investigated in a device simulation when the withstand voltage is maintained.

In the comparative example, as the cell size increases, a carrier accumulation effect increases, the ON voltage decreases and the characteristic improves, whereas the withstand voltage conversely decreases. Causes for this will be described using FIG. 14. As enclosed with a dotted line in FIG. 14, a high electric field is observed in a junction between the p-type base layer 4 and the n⁺-type layer 5 apart from the trench gate 9. For this reason, as the cell size increases, the electric field between the trenches increases and the withstand voltage decreases.

On the other hand, according to the present embodiment, the p-type well region 11 which is deeper than the trenches is formed in a dummy region which is wider than the cell region. As shown in FIG. 15, the presence of the p-type well region 11 relaxes concentration of the electric field between the trenches compared to the comparative example in FIG. 14. For this reason, even when the cell size increases, the withstand voltage can be improved while securing a low ON voltage as shown in FIGS. 12 and 13.

The inter-layer insulating film 15 insulates and separates the p-type well region 11 from the emitter electrode 14, thus closing release paths of holes. This facilitates accumulation of carriers in the n-type semiconductor substrate 3 in an ON state, and can thereby reduce the ON voltage.

Furthermore, the p-type well regions 11 surround the end portions of the trenches 8, 9 and 10, and thereby relax the electric field at the trench bases of the end portions, and can thus improve the withstand voltage.

Before forming the trenches 8, 9 and 10, the p-type well regions 11, the p-type base layer 4 and the n⁺-type layer 5 are formed in order. Thus, the characteristic can be stabilized by forming the p-type well regions 11 which are deep impurity diffusion layers first.

Furthermore, the p-type well region 11 in the termination region 2 arranged so as to surround the transistor region 1 and the p-type well region 11 between the trench 9 and the trench 10 are formed in the same process. It is thereby possible to reduce the manufacturing cost through a reduction in the number of steps.

Furthermore, since it is possible to reduce a heat treatment time by injecting an impurity with an enlarged range of ions and with high energy of 1 MeV or above to form the p-type well region 11, it is possible to reduce lateral diffusion of the p-type well region 11.

### Second Embodiment

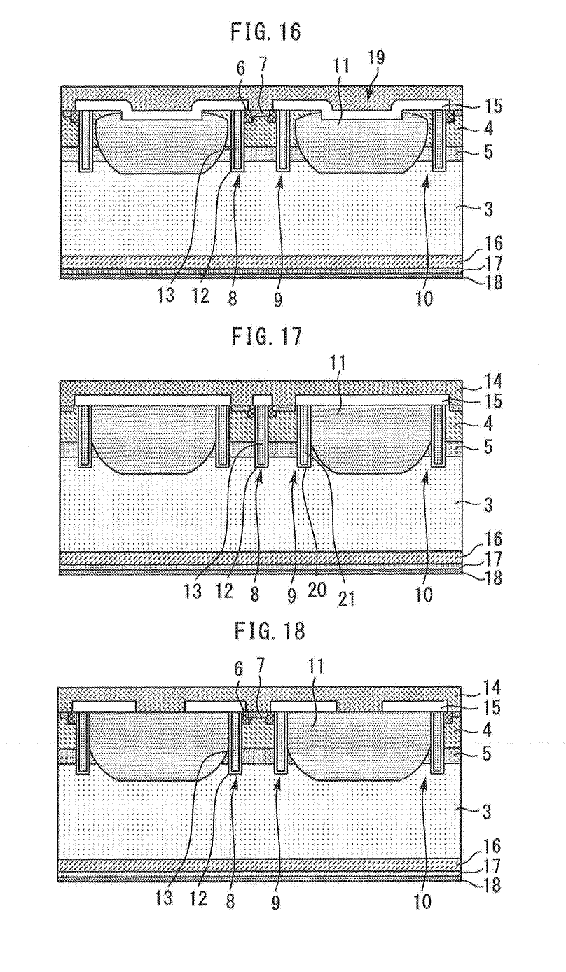

FIG. 16 is a cross-sectional view illustrating a method for manufacturing a semiconductor device according to a second embodiment of the present invention. In the present embodiment, a concave section 19 is formed on a front surface of the n-type semiconductor substrate 3 by etching. The p-type well region 11 is formed by injecting the impurity into a part in which the concave section 19 is formed.

By forming the concave section 19 on the front surface of the n-type semiconductor substrate 3, it is possible to form the p-type well region 11 deeply and thereby improve the withstand voltage.

Furthermore, since a heat treatment time to obtain a desired depth from the front surface can be reduced by an amount corresponding to the formation of the concave section 19, it is possible to reduce lateral diffusion of the p-type well region 11. Therefore, since the impurity is hardly diffused to the narrow MOS transistor region even when there are manufacturing variations in a photoengraving process of the p-type well region 11 and trenches or the like, it is possible to suppress variations in transistor electric characteristics.

### Third Embodiment

FIG. 17 is a cross-sectional view illustrating a semiconductor device according to a third embodiment of the present invention. The n⁺-type emitter layers 6 are formed on both sides of the trench 8 and the emitter electrode 14 is electrically connected to the p-type base layer 4 and the n⁺-type emitter layer 6 on both sides of the trench 8. Since a feedback capacitance determined by a gate-collector capacitance can be reduced more than in the first embodiment, a switching speed increases and it is thereby possible to reduce switching loss.

Furthermore, a dummy trench gate electrode 21 is formed in the trenches 9 and 10 via an insulating film 20, and electrically connected to the emitter electrode 14. Since the cell region is separated from a dummy region that holds the withstand voltage by the dummy trench gate electrode 21, it is possible to make operation of the transistor stable.

### Fourth Embodiment

FIG. 18 is a cross-sectional view illustrating a semiconductor device according to a fourth embodiment of the present invention. The inter-layer insulating film 15 is provided with openings and the p-type well region 11 is electrically connected to the emitter electrode 14.

Here, a latch-up is produced by operation of an npn transistor which is formed of the n⁺-type emitter layer 6, the p-type base layer 4 and the n-type semiconductor substrate 3 on the front surface in a transient situation such as when an IGBT is switched. To prevent such an operation, it is effective to reduce a hole current flowing from the rear surface into the p-type base layer 4 immediately below the n⁺-type emitter layer 6.

Thus, as in the present embodiment, the p-type well region 11 is connected to the emitter electrode 14, and a hole current thereby flows not toward the MOS transistor side but toward the p-type well region 11 side. Although this causes the ON voltage to increase, the latch-up resistance improves.

Furthermore, the p-type well region 11 preferably has a higher impurity concentration than that of the p-type base layer 4. This facilitates flowing of the hole current into the low-resistance p-type well region 11, and can thereby further improve the latch-up resistance.

Note that the semiconductor substrate is not limited to one formed of silicon, but may be formed of a wide-bandgap semiconductor having a wider bandgap than silicon. Examples of the wide-bandgap semiconductor include silicon carbide, nitride-gallium-based material or diamond. The semiconductor device formed of such a wide-bandgap semiconductor has a high withstand voltage and a high allowable current density, and can therefore be downsized. Using this downsized semiconductor device also allows a semiconductor module incorporating such a device to be downsized. Moreover, since the semiconductor device has high heat resistance, it is possible to downsize radiator fins of its heat sink, adopt an air cooling system instead of a water cooling system and further downsize the semiconductor module. Furthermore, the device has low power loss and high efficiency, and it is thereby possible to provide a more efficient semiconductor module.

### Reference Signs List

1 transistor region; 2 termination region; 3 n-type semiconductor substrate; 4 p-type base layer; 5 n⁺-type layer; 6 n⁺-type emitter layer; 8,9,10 trench; 11 p-type well region; 12,20 insulating film; 13 trench gate electrode; 14 emitter electrode; 15 inter-layer insulating film; 17 p⁺-type collector layer; 18 collector electrode; 19 concave section; 21 dummy trench gate electrode

1. A semiconductor device comprising:
an n-type semiconductor substrate;
a p-type base layer formed on a front surface side of the n-type semiconductor substrate;
an n-type layer formed below the p-type base layer on the front surface side of the n-type semiconductor substrate and having a higher impurity concentration than that of the n-type semiconductor substrate;
an n-type emitter layer formed on the p-type base layer;
first, second and third trenches formed on the front surface side of the n-type semiconductor substrate and penetrating the p-type base layer and the n-type layer;
a trench gate electrode formed in the first trench via an insulating film;
an emitter electrode formed on the p-type base layer and the n-type emitter layer and electrically connected to the p-type base layer and the n-type emitter layer respectively;
a p-type collector layer formed on a rear surface side of the n-type semiconductor substrate;
a collector electrode connected to the p-type collector layer; and
a p-type well region formed on the front surface side of the n-type semiconductor substrate,
wherein a distance between the first trench and the second trench is smaller than a distance between the second trench and the third trench,
the n-type emitter layer is formed in a cell region between the first trench and the second trench,
the p-type well region is formed in a dummy region between the second trench and the third trench,
an outermost surface part of the n-type semiconductor substrate is of only a p-type in the dummy region, and
the p-type well region is deeper than the first, second and third trenches.

2. The semiconductor device according to claim 1, wherein the p-type well region exists in plurality in mutually separate regions in a plan view perpendicular to the front surface of the n-type semiconductor substrate, and the p-type well regions are connected to each other to surround end portions of the first, second and third trenches.

3. The semiconductor device according to claim 1, wherein the n-type emitter layer is formed on both sides of the first trench and the emitter electrode is electrically connected to the p-type base layer and the n-type emitter layer on both sides of the first trench.

4. The semiconductor device according to claim 1, further comprising a dummy trench gate electrode formed in the second and third trenches via an insulating film and electrically connected to the emitter electrode.

5. The semiconductor device according to claim 1, further comprising an inter-layer insulating film insulating and separating the p-type well region from the emitter electrode.

6. The semiconductor device according to claim 1, wherein the p-type well region is electrically connected to the emitter electrode.

7. The semiconductor device according to claim 6, wherein the p-type well region has a higher impurity concentration than that of the p-type base layer.

8. A manufacturing method for a semiconductor device comprising:
forming a p-type base layer on a front surface side of an n-type semiconductor substrate;
forming an n-type layer below the p-type base layer on the front surface side of the n-type semiconductor substrate wherein the n-type layer has a higher impurity concentration than that of the n-type semiconductor substrate;
forming an n-type emitter layer on the p-type base layer;
forming first, second and third trenches on the front surface side of the n-type semiconductor substrate wherein the first, second and third trenches penetrate the p-type base layer and the n-type layer;
forming a trench gate electrode in the first trench via an insulating film;
forming an emitter electrode on the p-type base layer and the n-type emitter layer wherein the emitter electrode is electrically connected to the p-type base layer and the n-type emitter layer respectively;
forming a p-type collector layer on a rear surface side of the n-type semiconductor substrate;
forming a collector electrode connected to the p-type collector layer; and
forming a p-type well region on the front surface side of the n-type semiconductor substrate,
wherein a distance between the first trench and the second trench is smaller than a distance between the second trench and the third trench,
the n-type emitter layer is formed in a cell region between the first trench and the second trench,
the p-type well region is formed in a dummy region between the second trench and the third trench,
an outermost surface part of the n-type semiconductor substrate is of only a p-type in the dummy region, and
the p-type well region is deeper than the first, second and third trenches.

9. The manufacturing method for a semiconductor device according to claim 8, comprising:
forming a concave section on the front surface of the n-type semiconductor substrate by etching; and
forming the p-type well region by injecting an impurity into a part of the n-type semiconductor substrate in which the concave section is formed.

10. The manufacturing method for a semiconductor device according to claim 8, wherein the p-type well region, the p-type base layer and the n-type layer are formed in order before forming the first, second and third trenches.

11. The manufacturing method for a semiconductor device according to claim 8, wherein the p-type base layer and the n-type layer are formed by impurity injection using a single mask.

12. The manufacturing method for a semiconductor device according to claim 8, wherein the p-type well region in a termination region arranged so as to surround a transistor region and the p-type well region between the second trench and the third trench are formed in the same process.

13. The manufacturing method for a semiconductor device according to claim 8, wherein an impurity is injected with energy of 1 MeV or above to form the p-type well region.
